(19) United States
(12) Patent Application Publication
(10) Pub. No.: US 2019/0043694 A1
(43) Pub. Date: Feb. 7, 2019

(54) PLASMA PROCESSING APPARATUS AND METHOD FOR MANUFACTURING SEMICONDUCTOR DEVICE USING THE SAME

(71) Applicant: SAMSUNG ELECTRONICS CO., LTD., SUWON-SI (KR)

(72) Inventor: CHAN HOON PARK, Osan-si (KR)

(21) Appl. No.: 15/894,152

(22) Filed: Feb. 12, 2018

(30) Foreign Application Priority Data
Aug. 3, 2017 (KR) 10-2017-0098310

(51) Int. Cl. H01J 37/32; H01L 21/3065; H01L 21/67

(52) U.S. Cl. CPC H01J 37/32091; H01J 37/32174; H01L 21/3065; H01L 21/308; H01J 2237/334; H01J 2237/327; H01L 21/67069

(57) ABSTRACT

A plasma processing apparatus includes a chamber, a first electrode disposed in the chamber configured to receive a substrate loaded on the first electrode. A second electrode disposed in the chamber is opposed to the first electrode, and an RF power source is configured to switch between an on-state and an off-state. The RF power source supplies a source RF power to the first or the second electrode and supplies a bias RF power to the first electrode in the on-state. A first DC voltage supply alternately supplies a first DC voltage of negative polarity and a second DC voltage of negative polarity to the second electrode depending status of the first RF power source. The second DC voltage supply is turned on between first and second cycles where the first DC voltage is output to supply a third DC voltage of positive polarity to the first electrode.

This application claims priority from Korean Patent Application No. 10-2017-0098310 filed on Aug. 3, 2017 in the Korean intellectual Property Office, the disclosure of which is incorporated by reference herein in its entirety.

### 1. TECHNICAL FIELD

The inventive concept relates to a plasma processing apparatus and a method for manufacturing a semiconductor device using the same.

### 2. DISCUSSION OF THE RELATED ART

In a semiconductor manufacturing process, a plasma processing apparatus is used to etch a semiconductor substrate using plasma. A variety of types of plasma processing apparatuses are used. For example, a capacitive coupled plasma (CCP) system is commonly used.

In the CCP system, a pair of flat plate electrodes (upper and lower electrodes) are disposed in parallel in a chamber in a vacuum state. A process gas is inserted into the chamber, and by applying a radio frequency (RF) power to one of the electrodes, an electric field is generated between the electrodes. The gas in the chamber is excited into a plasma state by the RF electric field. A semiconductor substrate (e.g., a wafer) is placed on one of the electrodes, and is etched by using ions and electrons from the plasma to etch the semiconductor substrate.

Recently, higher aspect ratios are being used to increase the capacity of DRAM (dynamic random access memory) or to increase the storage space of VNAND. As the aspect ratio increases, however, the etching process becomes more and more difficult to perform. Particularly, as the aspect ratio increases, positively charged ions (cations) are charged in a trench or a contact hole, such that the etch rate is reduced. As a result of increasing the aspect ratio, there may he issues such as poor mask selectivity and a decrease in unit per equipment hour (UPEH).

### SUMMARY

The present inventive concept provides a plasma processing apparatus that can suppress the phenomenon whereby cations are charged on the bottom of a contact hole or a trench (“bottom charging”) while a plasma power source is turned off, and can increase the etch rate by improving depth loading.

The inventive concept is not limited to the above discussion. Embodiments of the inventive concept disclosed herein are provided for illustrative purposes and the appended claims are not limited to the following description.

According to some embodiments of the inventive concept, the plasma processing apparatus may include a chamber configured to receive a gas; a first electrode disposed in the chamber, the first electrode configured to receive a substrate loaded thereon; a second electrode disposed in the chamber that is opposed to the first electrode; a RF power source configured to be switched between an on-state and an off-state, the RF power source further configured to supply a source RF power to the first electrode or the second electrode and to supply a bias RF power to the first electrode in the on-state to generate an RF electric field between the first electrode and the second electrode that excites the gas in the chamber into a plasma state; a first DC voltage supply configured to alternately supply a first DC voltage of negative polarity and a second DC voltage of negative polarity to the second electrode based on a state of the RF power source, wherein an absolute value of the second DC voltage is greater than an absolute value of the first DC voltage; and a second DC voltage supply is configured to he turned on between a first cycle and a second cycle when the first DC voltage is output to supply a third DC voltage of positive polarity to the first electrode.

According to some embodiments of the inventive concept, the plasma processing apparatus may include a chamber, a first electrode disposed in the chamber, wherein a substrate is loaded on the first electrode, and a second electrode may be disposed in the chamber that is opposed to the first electrode, an RF power source configured to be turned on from a first time to a second time to supply a source RF power to the first electrode or to the second electrode and to supply a bias RF power to the first electrode, and the RF power source configured to be turned off from the second time to a third time, a first DC power supply configured to supply a first DC voltage of negative polarity to the second electrode from the first time to the second time, and to supply a second DC voltage of negative polarity to the second electrode from the second time to the third time, wherein an absolute value of the second DC voltage is greater than an absolute value of the first DC voltage; and a second DC power supply, wherein the second DC power supply is turned on between the second time and the third time to supply a third DC voltage of positive polarity to the first electrode.

According to some embodiments of the inventive concept, a method for manufacturing a semiconductor device performed by a plasma processing apparatus, the apparatus including a chamber, a first electrode disposed in the chamber, wherein a substrate is loaded on the first electrode, a second electrode disposed in the chamber to oppose to the first electrode, an RF power source configured to supply a source RF power to the first electrode or the second electrode and to supply a bias RF power to the first electrode when it is turned on, a first DC power supply configured to supply a first DC voltage or a second DC voltage of negative polarity to the second electrode, wherein an absolute value of the second DC voltage is greater than an absolute value of the first DC voltage, and a second DC power supply configured to supply a third DC voltage of positive polarity to the first electrode when turned on, wherein the method comprises supplying the first DC voltage to the second electrode from the first DC power supply, and turning on the RF power source from a first time to a second time to etch the substrate so that a contact hole or a trench is formed therein to a first depth, turning off the RF power source, supplying the second DC voltage to the second electrode from the first DC power supply from the second time to a third time, and turning on the second DC power supply between the second time and the third time, to migrate anions and electrons in the chamber into the contact hole or the trench and supplying the first DC voltage to the second electrode from the first DC power supply and turning on the RF power source from the third time to a fourth time, to etch the substrate so that the contact hole or the trench becomes deeper the first depth.

The inventive concept includes a semiconductor device constructed according to the method of the inventive concept. Such a semiconductor device is constructed with a higher aspect ratio than known heretofore without a decrease in the etch rate.

According to some embodiments of the inventive concept a plasma processing apparatus, may include a chamber having a worktable configured to receive a substrate, the chamber including a gas inlet and a gas outlet; an RF power source configured to be switched between an on-state and an off-state, and an RF antenna to generate an RF electric field in the chamber that excites a gas in the chamber into a plasma state; a first DC voltage supply is configured to alternately supply a first DC voltage of negative polarity and a second DC voltage of negative polarity based on a state of the RF power source, wherein an absolute value of the second DC voltage is greater than an absolute value of the first DC voltage; and a controller configured to turn on the RF power source from a first time to a second time so that plasma gas etches the substrate on the worktable to form a contact hole or a trench therein having a first depth, and to turn off the RF power source and supply the second DC voltage from the first DC voltage supply from the second time to a third time, and the controller is configured to turn off the second DC voltage supply between the second time and the third time to migrate anions and electrons in the chamber into the contact hole or the trench.

According to an embodiment of the plasma processing apparatus, the controller is further configured to control the first DC voltage supply to supply the first DC voltage and turn on the RF power source from the third time to a fourth time to etch the substrate so that the contact hole or the trench becomes deeper the first depth.

A person of ordinary skill in the art should understand and appreciate that the present inventive concept is not restricted to the descriptions set forth herein. The above and other aspects of the present inventive concept will become better appreciated by one of ordinary skill in the art to which the present inventive concept pertains by referencing the detailed description of the present inventive concept given below.

### BRIEF DESCRIPTION OF THE DRAWINGS

The above and other features of the inventive concept will be better appreciated by a person of ordinary skill in the art by describing in detail exemplary embodiments thereof with reference to the attached drawings, in which:

FIGS. 1 and 2 are block diagrams for illustrating plasma processing apparatuses according to some embodiments of the inventive concept;

FIG. 3 is a flowchart for illustrating the operation of the plasma processing apparatuses according to some embodiments of the inventive concept;

FIGS. 4 to 7 are timing diagrams illustrating operation of the plasma processing apparatuses according to some embodiments of the inventive concept, in which:

FIG. 4 shows the second DC voltage supply may be turned on during a second cycle t2 to t3;

FIG. 5 shows the second DC voltage supply turned on at a fourth time to after a certain period of time has elapsed since the RF power source was turned off;

FIG. 6 shows the second DC voltage supply turned on at time t2 and turned off at a fifth time tb before the end of the second cycle at t3;

FIG. 7 shows the second DC voltage supply turned on at time to when a predetermined period of time has elapsed and turned off at the fifth time tb before the end of second cycle at t3;

FIG. 8 is a diagram illustrating a phenomenon that occurs when a positive DC voltage is supplied to the second electrode immediately after the RF power source is turned off;

FIG. 9 is a graph showing the change in the number of electrons that generate the plasma potential when the RF power source is turned off; and

FIGS. 10 to 13 are diagrams illustrating a method for performing a plasma etching process on a substrate loaded in a plasma processing apparatus according to some exemplary embodiments of the inventive concept in which:

FIG. 10 shows a wafer W loaded onto a first electrode in a chamber that is configured for plasma etching;

FIG. 11 shows radicals and/or ion particles contained in the gas excited into the plasma state to etch the wafer W so that a contact hole C is formed to a first depth H1;

FIG. 12 shows cations contained in the gas excited into the plasma state in the chamber collide with the second electrode to generate secondary electrons that migrate into the contact hole C to weaken the electromagnetic field generated by the cations charged in the contact hole C; and

FIG. 13 shows a state in which the radicals and/or ion particles contained in the gas in the plasma state etch the substrate (e.g., the wafer W) so that the contact hole C becomes deeper (H2) than the first depth H1 shown in FIG. 11.

### DETAILED DESCRIPTION

During a process of etching a wafer with a plasma processing apparatus, cations (e.g., positively charged ions) may be accumulated in a contact hole or a trench formed in the wafer.

In another words, a phenomenon occurs during the etching of the wafer with plasma such that cations are charged on the bottom of a contact hole or a trench (“bottom charging”). This phenomenon may reduce the energy of the cations that migrate into a contact hole or a trench. When the energy of the cations is reduced, the etch rate of the plasma processing apparatus is reduced. In view of the above, methods according to some embodiments of the inventive concept which address the issue of the etch rate being reduced will be described below.

In the following description, capacitive coupled plasma (CCP) processing apparatuses will be described for convenience of illustration. It is, however, to be understood that exemplary embodiments of the inventive concept are not limited to the capacitively coupled plasma processing apparatuses, but may also be applied to an inductively coupled plasma (ICP) processing apparatus, a plasma processing apparatus using microwave, a plasma processing apparatus using electron cyclotron resonance (ECR), etc.

In addition, a person of ordinary skill in the art will understand and appreciate that, for example, in an ICP processing apparatus, there would be, for example, an electromagnetic source (coils) arranged to induce an electromagnetic field in the chamber to excite an inlet gas and generate plasma. In addition, a plasma processing apparatus using microwave would include, for example, a chamber with a microwave transmission window, and an antenna unit with a waveguide. However, the inventive concept is applicable to at least all of these types of plasma processing apparatuses, and may result in semiconductor having higher aspect ratios without a reduction in the etch rate.

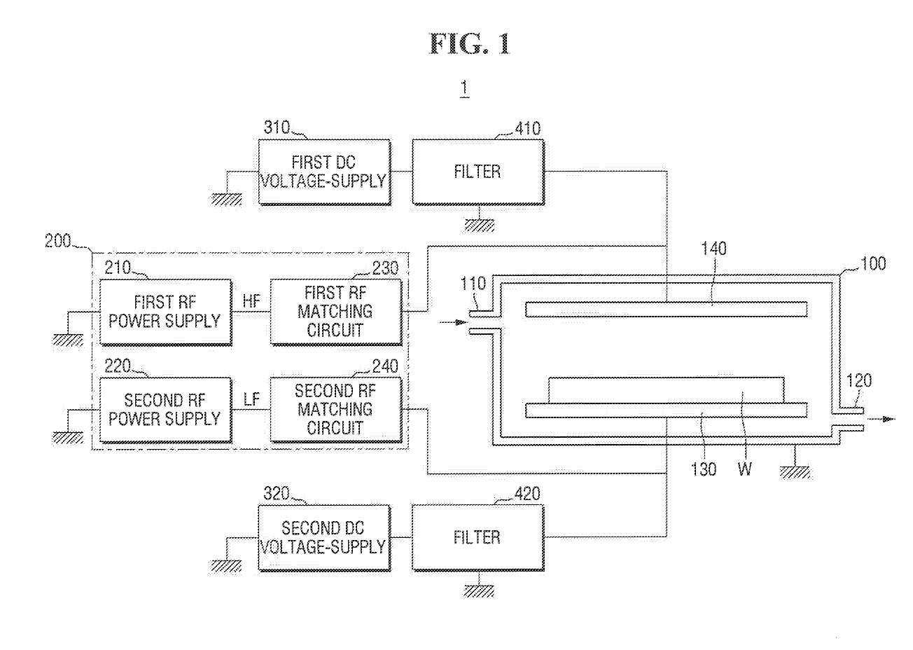

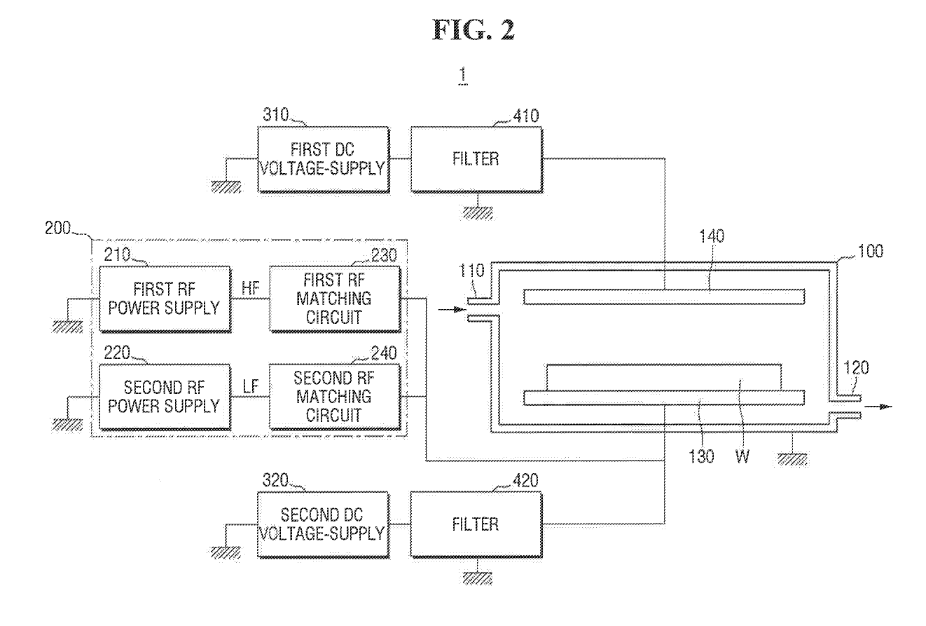

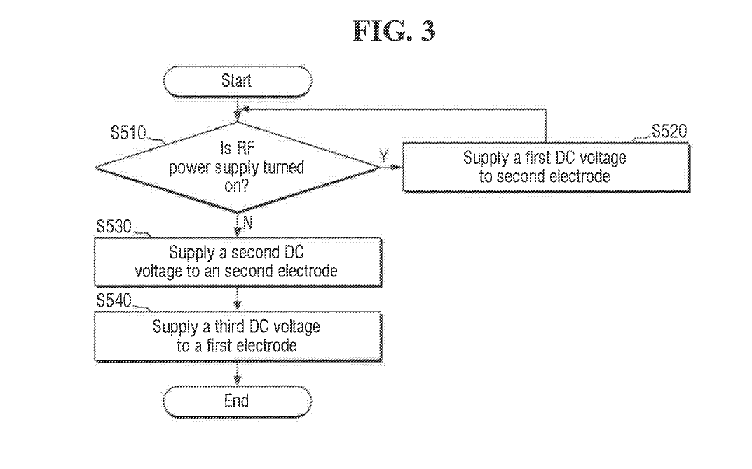

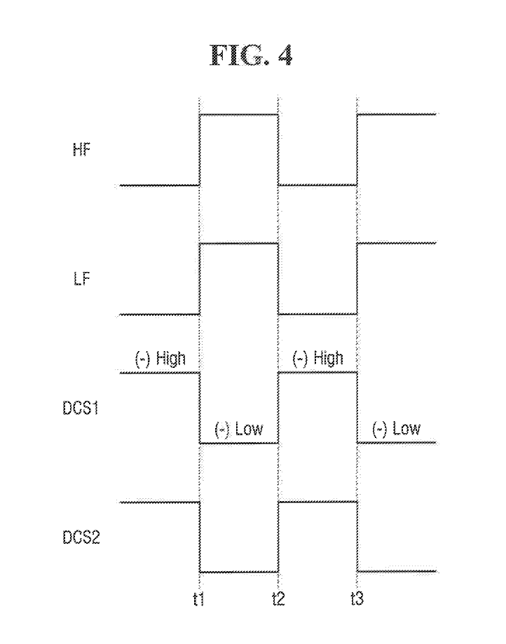

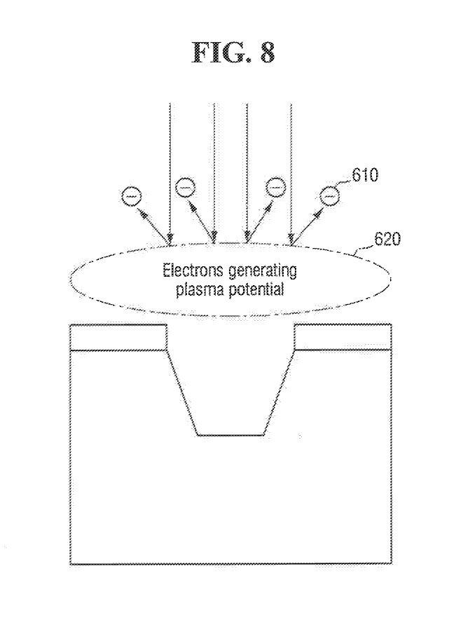

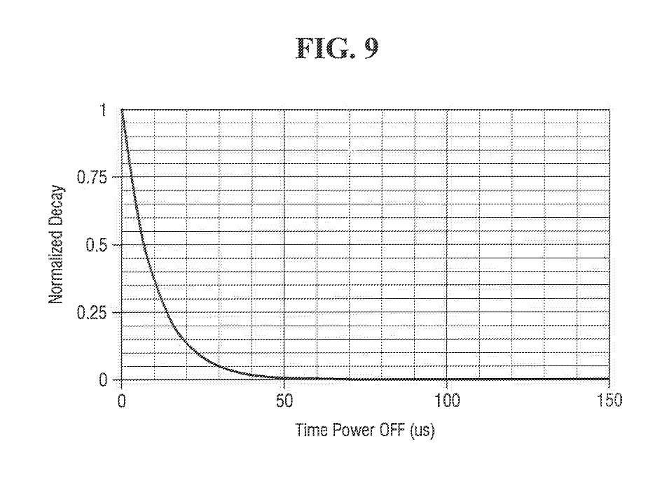

FIGS. 1 and 2 are block diagrams for illustrating plasma processing apparatuses according to some exemplary embodiments of the inventive concept. FIG. 3 is a flowchart for illustrating the operation of the plasma processing apparatuses according to some embodiments of the inventive concepts. FIGS. 4 to 7 are timing diagrams illustrating operation of the plasma processing apparatuses according to some embodiments. FIG. 8 is a diagram illustrating a phenomenon that occurs when a positive DC voltage is supplied to the second electrode immediately after the RF power source is turned off. FIG. 9 is a graph showing the change in the number of electrons that generate the plasma potential when the RF power source is turned off.

Referring now to FIGS. 1 and 2, a plasma processing apparatus 1 may include a chamber 100, an RF power source 200, a first DC voltage supply 310, a second DC voltage supply 320, and filters 410 and 420. The elements shown in FIGS. 1 and 2 are one example regarding implementation of the plasma processing apparatus 1 according to the inventive concept. In some embodiments, the plasma processing apparatus 1 may have more elements or fewer elements than those disclosed above and shown in the drawings. For example a controller (not shown) may include integrated circuitry configured to control, for example, operation of the first RF power supply 210, the second RF power supply 220, the first DC voltage supply 310, the second DC voltage supply 320, the first RF matching circuit 230, and the second RF matching circuit 240. In the case of a microwave plasma processing apparatus, or an ICP, or an ECR type, there may also be at least one antenna or an antenna array (not shown), a waveguide (not shown), and the chamber may have a transmission window (not shown).

The chamber 100 may be a vacuum processing chamber in which a semiconductor manufacturing process using plasma is carried out. The chamber 100 may be connected to the ground potential.

The chamber 100 may include a gas inlet 110 and a gas outlet 120. The gas supplied via the gas inlet 110 may be excited into a plasma state by the RF power source 200. The gas excited into the plasma state may be used in a process of etching a wafer W or the like which is a semiconductor substrate.

With continued reference to FIG. 1, in the chamber 100, a first electrode 130 on which a substrate (e.g., a wafer W) is loaded, and a second electrode 140 may be arranged within the change so as to be opposed to the first electrode 130. The first electrode 130 and the second electrode 140 may be, for example, flat-plate conductors that supply RF power into the chamber 100 to excite the gas supplied into the chamber 100 into a plasma state.

A semiconductor substrate such as a wafer W, e.g., a workpiece, may be placed on the first electrode 130.

The first electrode 130 may be disposed at the lower portion of the chamber 100. The second electrode 140 may be disposed at the upper portion of the chamber 100 in parallel with the first electrode 130.

The RF power source 200 may include a first RF power supply 210, a second RF power supply 220, a first RF matching circuit 230, and a second RF matching circuit 240.

The first RF power supply 210 may output high frequency (HF) power having a frequency (e.g., about 40 MHz) that is suitable for plasma generation. The type of gas being excited to a plasma state may have an optimal frequency range for plasma generation by the HF power. The power output from the first RF power supply 210 may be an RF power source.

The second RF power supply 220 may output a low frequency (LF) power having a frequency (e.g., about 12.88 MHz) that is suitable for the attraction of ions from the plasma to the semiconductor wafer W to facilitate etching of the semiconductor wafer W. There may also be an optimal frequency range for the LF power to attract the ions from the plasma to the semiconductor wafer W. The power output from the second RF power supply 220 may be a bias RF power.

The first RF matching circuit 230 may be configured to match the impedances to transfer the maximum power of the HF power output from the first RF power supply 210 to the first electrode 130 or to the second electrode 140.

For example, referring to FIG. 1, the first RF matching circuit 230 may be connected between the first RF power supply 210 and the second electrode 140. The impedances may be matched by the first RF matching circuit 230 so as to transfer the maximum power of the HF power output from the first RF power supply 210 to the second electrode 140.

For another example, referring to FIG. 2, the first RF matching circuit 230 may be connected to the first RF power supply 210 and the first electrode 130. The impedances may be matched by the first RF matching circuit 230 so as to transfer the maximum power of the HF power output from the first RF power supply 210 to the first electrode 130.

Referring again to FIGS. 1 and 2, the second RF matching circuit 240 may be connected between the second RF power supply 220 and the first electrode 130. The second RF matching circuit 240 may match the impedances to transfer the maximum power of the LF power output from the second RF power supply 220 to the first electrode 130.

The state of the RF power source 200 may be switched between an on-state and an off-state. When the RF power source 200 is turned on, the source RF power may be supplied to the first electrode 130 or the second electrode 140, and the bias RF power may be supplied to the first electrode 130. The RF power source 200 does not supply the source RF power and the bias RF power when it is turned off.

For example, the RF power source 200 may be turned on from a first time t1 to a second time t2 (see FIGS. 4 to 7), such that it may supply the source RF power to the first electrode 130 or the second electrode 140 and may supply the bias RF power to the first electrode 130 (see HF and LF in FIGS. 4 to 7). The RF power source 200 may be turned off from a second time t2 to a third time t3 (see FIGS. 4 to 7), such that it may supply neither source RF power nor bias RF power to the first electrode 130 and the second electrode 140 (see HF and LF in FIGS. 4 to 7). In addition, the RF power source 200 may be turned on again at the third time t3 (see FIGS. 4 to 7).

The filters 410 and 420 may allow the DC voltage output from the first DC voltage supply 310 and the second DC voltage supply 320 to pass therethrough. The filters 410 and 420 may lead the HF and LF powers output from the RF power source 200 to the ground line. For example, the filters 410 and 420 may block the HF and LF powers from flowing to the first DC voltage supply 310 and the second DC voltage supply 320, respectively.

The first DC voltage supply 310 may supply the second electrode 140 with a first DC voltage of negative polarity or a second DC voltage of negative polarity that has an absolute value different from that of the first DC voltage, depending on the state of the RF power source. The absolute value of the first DC voltage may be smaller than the absolute value of the second DC voltage.

For example, the first DC voltage may be −500 V, while the second DC voltage may be −1000 V. It is to be understood that the above-described values are examples, and the first DC voltage and the second DC voltage value may have different values. Nor should any ratio of first DC voltage to second DC voltage he presumed by the value of the example voltages provided herein.

Referring now to FIG. 3, at operation (S510) the plasma processing apparatus may determine whether the RF power source is turned on. If the RF power source is turned on (“Yes” in operation S510), then at operation (S520) the first DC voltage supply 310 may supply the first DC voltage to the second electrode 140 (upper electrode). Subsequently, the plasma processing apparatus may keep checking whether the RF power source is turned on (operation S510).

On the other hand, still referring to FIG. 3, if at operation (S510) the RF power source is turned off (“No” at operation S510), then at operation (S530), the first DC voltage supply 310 may supply the second DC voltage to the second electrode 140.

Referring to DCS1 of FIGS. 4 to 7, from the first time t1 to the second time t2 while the RF power source is turned on, the first DC voltage supply 310 may supply the second electrode 140 with the first DC voltage that has the negative polarity and has a smaller absolute value than the second DC voltage. From the second time t2 to the third time t3 while the RF power source is turned off, the first DC voltage supply 310 may supply the second electrode 140 with the second DC voltage that has the negative polarity and has a larger absolute value than the first DC voltage. In addition, the first DC voltage supply 310 may supply the first DC voltage to the second electrode 140 again when the RF power source is turned on again at the third time t3.

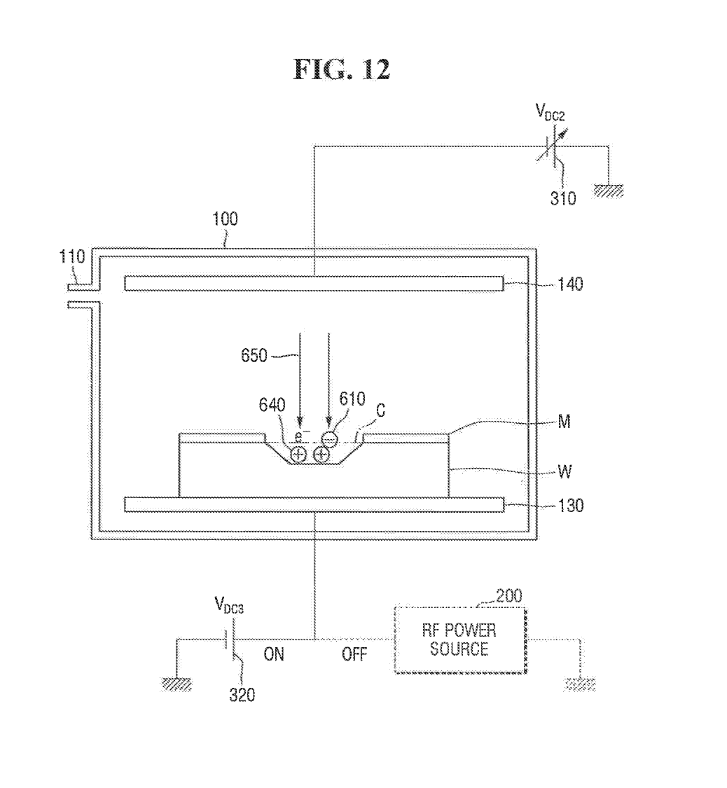

When the first DC voltage supply 310 supplies the second DC voltage to the second electrode 140 from the second time t2 to the third time t3, secondary electrons 650 may be generated through the second electrode 140. This operation will be described later in detail with reference to FIG. 12.

Referring again to FIG. 3, at operation (S540), the second DC voltage supply 320 may supply a third DC voltage of the positive polarity to the first electrode 130.

For example, referring to DCS2 of FIG. 4, the second DC voltage supply 320 may be turned on during a second cycle t2 to t3 between the first cycle t1 to t2 and the third cycle t3 and later, in each of which the first DC voltage is supplied through the first DC voltage supply 310, to supply the third DC voltage of the positive polarity to the first electrode 130.

For another example, the second DC voltage supply 320 may be turned off from the first time t1 when the RF power source is in an on-state to the second time t2. The second DC voltage supply 320 may be turned on from the second time t2 when the RF power source is in the off-state to the third time t3. The second DC voltage supply 320 may be turned off from the third time t3 when the RF power source is turned on again.

One way to prevent electric arcing may be setting a third DC voltage to have an absolute value corresponding to the absolute value of the second DC voltage. For example, if the second DC voltage is −1,000 V, then the third DC voltage may be 1,000 V. It is to be understood that the aforementioned is illustrative and the third DC voltage may have the maximum voltage to the extent that it does not cause electric arcing.

When the second DC voltage supply supplies the DC voltage of the positive polarity to the first electrode 130, e.g., the lower electrode, while the RF power source is turned off, anions 610 contained in the gas excited into the plasma state (for example, CF⁻, C⁻, F⁻, etc.) or electrons may migrate into contact holes or trenches of the substrate to be processed. Therefore, according to the inventive concept, the cations in the gas excited into the plasma state may be suppressed from being charged in the contact holes or the trenches by permitting the migration of anions 610 by turning off the RF power source while the second DC voltage supply is on.

Referring now to FIG. 8, if the second DC voltage supply is turned on immediately after the RF power source is turned off, the anions 610 contained in the gas excited into the plasma state may not migrate into a trench or a contact hole formed in the wafer. For example, there may be electrons 620 that generate a plasma potential over the wafer when the RF power source is turned off. These electrons 620 may hinder the anions 610 contained in the gas excited into the plasma state from migrating into the trench or contact hole formed in the wafer.

Accordingly, in some exemplary embodiments of the inventive concept, the second DC voltage supply may be turned on after a certain period of time has elapsed since the RF power source was turned off.

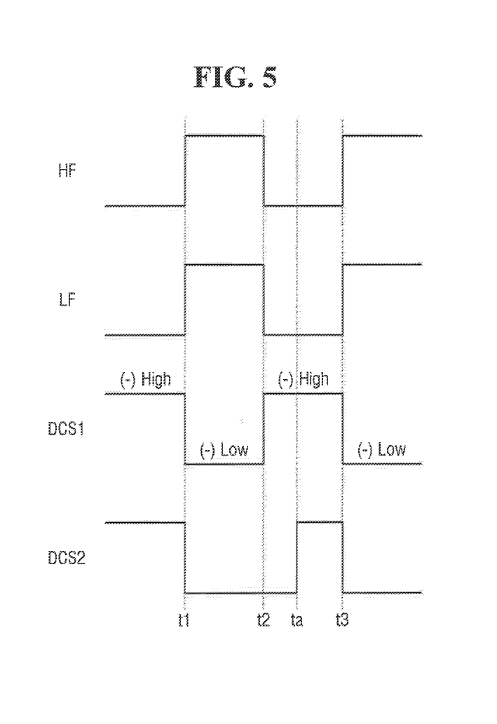

For example, referring to DCS2 of FIG. 5, the second DC voltage supply may be turned on at a fourth time ta after a certain period of time has elapsed since the RF power source was turned off. It is to be noted that the fourth time ta may lie between the first time t1 and the third time t3 where the first DC voltage supply supplies the first DC voltage at the DCS1 and also between the second time t2 and the third time t3 where the second DC voltage is supplied. Further, the fourth time ta may lie between the first cycle t1 to t2 and the third cycle t3 and later in each of which the first DC voltage supply supplies the first DC voltage. For example, the fourth time ta may be a time point when a predetermined period of time has elapsed since the end of the first cycle t1 to t2.

The fourth time ta may be a time point when the number of electrons generating the plasma potential becomes less than a predetermined value (for example, 0.01).

The aforementioned example will be described in more detail with reference to FIG. 9, which is a graph of normalized decay versus time power off in μs. In FIG. 9, the y-axis may represent the amount of relative change of electrons generating the plasma potential, and the x-axis may represent an elapsed time since the RF power source was turned off. Referring to FIG. 9, the number of electrons generating the plasma potential may exponentially decrease after the RF power source is turned off, to become below the predetermined value at 50 μs. Therefore, the fourth time to may be 50 μs. It is to be understood by a person of ordinary skill in the art that the aforementioned example is illustrative, and the predetermined value may vary in other implementations.

According to some embodiments of the inventive concept, by supplying the third DC voltage after the number of electrons generating the plasma potential becomes less than the predetermined value, it is possible to avoid the problem described above with respect to FIG. 8, in which electrons 620 that generate a plasma potential over the wafer when the RF power source is turned off may hinder the anions 610 contained in the gas excited into the plasma state from migrating into the trench or contact hole formed in the wafer.

According to some exemplary embodiments of the inventive concept, the second DC voltage supply unit may be turned off before the first DC voltage supply supplies the first DC voltage.

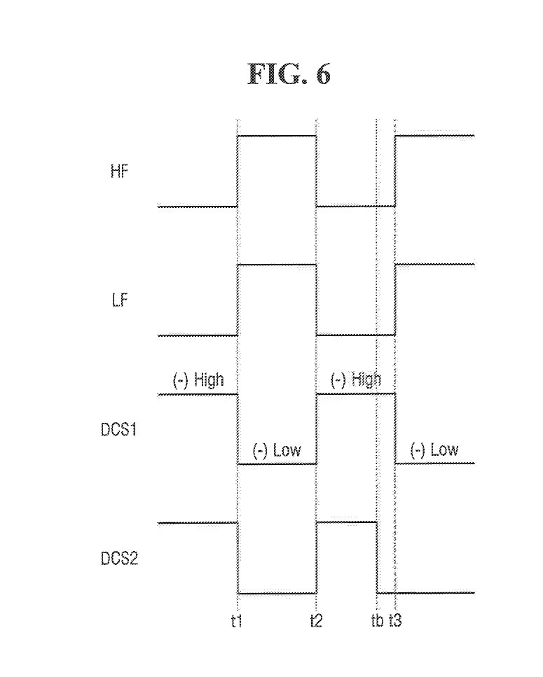

For example, referring to DCS2 of FIG. 6, the second DC voltage supply may be turned on at the second time t2 when the second DC voltage is supplied via the first DC voltage supply and may be turned off before the third time t3 when the first DC voltage supply 310 supplies the first DC voltage. For example, the second DC voltage supply 320 may be turned on at time t2 when the first cycle t1 to t2 during which the first DC voltage supply supplies the first DC voltage is ended, and may be turned off at the fifth time tb before the third cycle t3 and later is started.

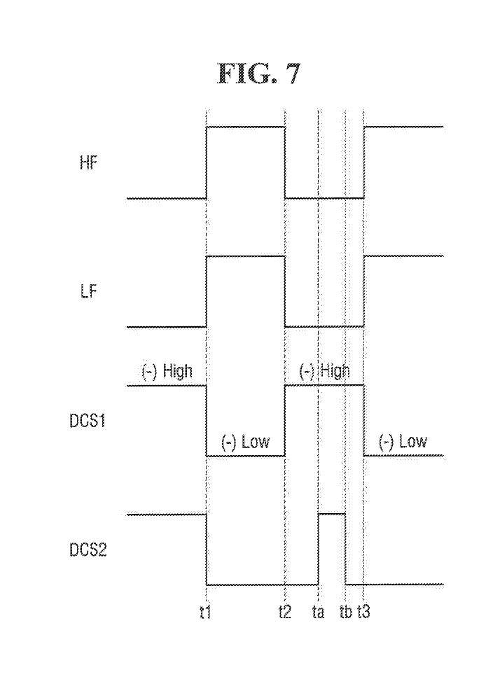

For another example, referring to DCS2 of FIG. 7, the second DC voltage supply unit may be turned on at the fourth time ta when a predetermined period of time has elapsed since the second time t2 when the first DC voltage supply supplies the second DC voltage, and may be turned off before the third time t3 when the first DC voltage supply 310 supplies the first DC voltage. For example, the second DC voltage supply 320 may be turned on at time ta when a predetermined period of time has elapsed since the end of the first cycle t1 to t2 where the first DC voltage supply supplies the first DC voltage, may be turned off at the fifth time tb before the third cycle t3 and later is started.

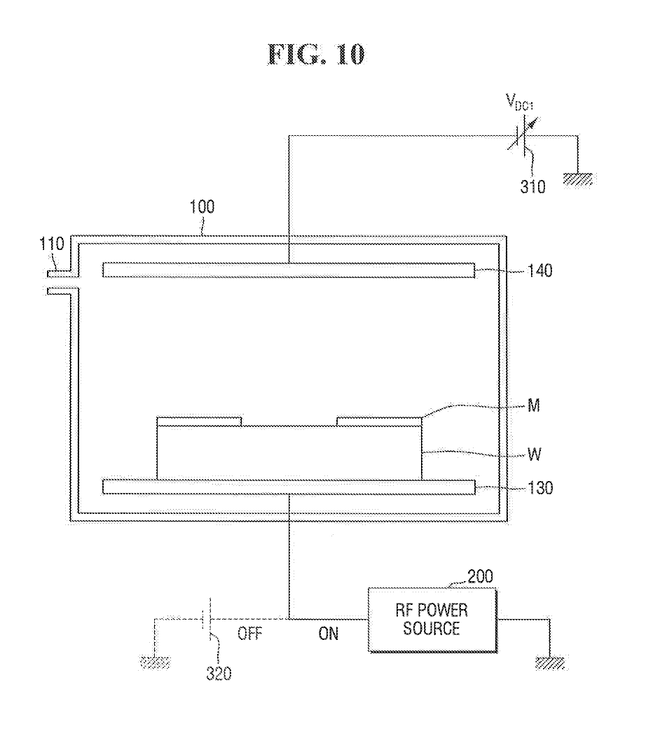

FIGS. 10 to 13 are diagrams illustrating a method for performing a plasma etching process on a substrate loaded in a plasma processing apparatus according to some exemplary embodiments of the inventive concept. For brevity, descriptions will be made focusing on differences from the above exemplary embodiments described with reference to FIGS. 1 to 9; and thus any redundant description will be omitted. Although it is assumed that the source RF power and the bias RF power are supplied to the first electrode 130 on which the substrate is loaded for convenience of illustration, this example is illustrative.

Referring to FIG. 10, a substrate to be processed, (e.g., a wafer W) may be transferred into the chamber 100. The wafer W transferred into the chamber 100 may be loaded on the first electrode 130. A mask pattern M may be formed on the wafer W in the chamber 100.

After the wafer W is loaded on the first electrode 130, a process gas may be injected into the chamber 100 via the gas inlet 110. The process gas injected into the chamber 100 may include C₄F₆, C₄F₈, CF₄, CHF₃, CH₂F₂, CH₃F, nitrogen, oxygen, argon, and the like.

When it is determined that the pressure of the process gas injected into the chamber 100 has reached the level sufficient to perform the etching process, the RF power source 200 may be turned on to supply the source RF power and the bias RF power to the first electrode 130. The first DC voltage supply 310 may supply the first DC voltage V_{DC1} having the negative polarity to the second electrode 140 while the RF power source 200 is turned on. In addition, the second DC voltage supply 320 may be turned off while the RF power source 200 is turned on.

When the RF power source 200 is turned on, an RF electric field is formed between the first electrode 130 and the second electrode 140. The gas injected into the chamber 100 can he excited into a plasma state by this RF electric field. The gas, when excited into the plasma state, may include radicals, ionic particles, and the like.

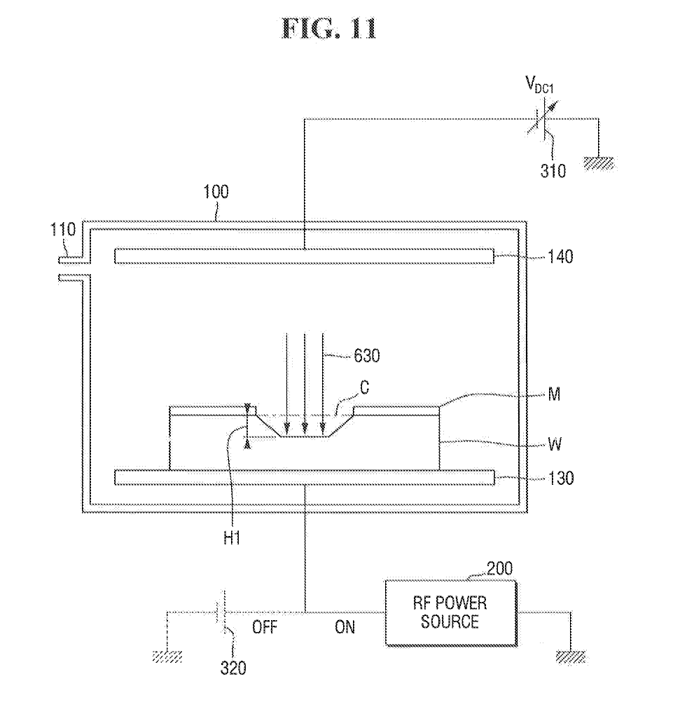

Referring to FIG. 11, the RF power source 200 may remain in the on-state from a first time to a second time. Meanwhile, radicals and/or ion particles 630 contained in the gas excited into the plasma state may etch the wafer W. The portion corresponding to the opening of the mask pattern M may be etched out. For example, the substrate (e.g., the wafer W) may be etched from the first time to the second time so that a contact hole C is formed to a first depth H1. Although the process of forming a contact hole is described for convenience of illustration, this illustration does not limit the inventive concept and the appended claims to etching a contact hole. For example, a trench may be formed by the etching process.

Referring now to FIG. 12, from the second time to the third time while the RF power source is turned off, the first DC voltage supply 310 may supply a second DC voltage V_{DC2} of the negative polarity having an absolute value larger than that of the first DC voltage V_{DC1} (see FIGS. 10 and 11) to the second electrode 140.

When the second DC voltage V_{DC2} is supplied to the second electrode 140, the cations 640 contained in the gas excited into the plasma state in the chamber 100 move toward the second electrode 140 to collide with it. As the cations collide with the second electrode 140, secondary electrons 650 may be generated. The generated secondary electrons 650 may move toward the wafer W. In this case, the secondary electrons 650 may migrate into the contact hole C formed in the wafer W, so that they may weaken the strong electromagnetic field (strong E-field) generated by the cations 640 charged in the contact hole C. Thus, the etched rate may not become reduced, as happens in plasma processing when the aspect ratio is increased to, for example, increase the capacity of DRAM, or to increase the storage space of VNAND.

Further, between the second time and the third time while the RF power source is turned off, the second DC voltage supply 320 may be turned on to supply the third voltage V_{DC3} of the positive polarity to the first electrode 130. In this case, the anions 610 contained in the gas excited into the plasma state may migrate into the contact hole C, thereby weakening the strong electromagnetic field generated by the cations 640 charged in the contact hole C.

The second DC voltage supply 320 may be turned on when the number of electrons 620 generating the plasma potential in the chamber 100 is less than a predetermined value. This condition has been described above with reference to FIGS. 5 and 8; and, therefore, a redundant description will be omitted.

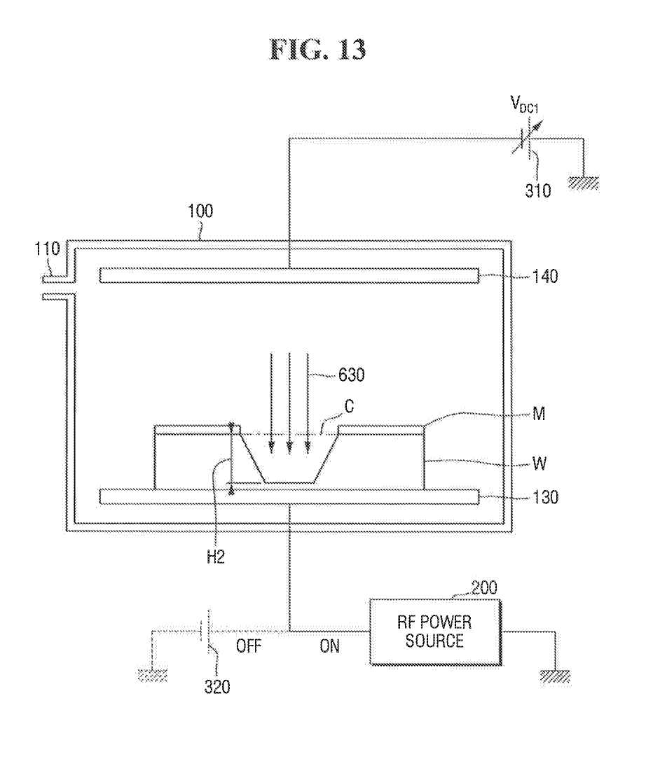

Referring now to FIG. 13, the RF power source may be turned on again from the third time to the fourth time. From the third time to the fourth time, the radicals and/or ion particles 630 contained in the gas in the plasma state may etch the substrate (for example, the wafer W) so that the contact hole C become deeper than the first depth H1 (see FIG. 11). For example, the wafer W may have a second depth H2 at the fourth time. The second depth H2 may be greater than the first depth H1 (see FIG. 11).

Since the strong electromagnetic field generated by the cations 640 charged in the contact hole C is weakened as described above with reference to FIG. 12, the time that elapses to etch the substrate to a desired depth to form the contact hole C can be saved. As a result, the etch rate can be improved.

Referring again to FIG. 13, from the third time to the fourth time while the RF power source 200 is turned on again, the first DC voltage supply 310 may supply the first DC voltage V_{DC1} to the second electrode 140 and the second DC voltage supply 320 may be turned off.

The RF power source 200 may he turned on and turned off continually until the contact hole formed in the substrate (e.g., wafer W) reaches a desired depth. Then, once the contact hole is formed in the substrate at a desired depth, the substrate (e.g., the wafer W) may be removed from the chamber 100.

The plasma processing apparatuses according to some exemplary embodiments of the inventive concept can be used for any product that uses a plasma etching process. In particular, the plasma processing apparatuses according to some exemplary embodiments of the inventive concept may be used for manufacturing a VNAND product, a DRAM product, a logic product, etc., that employ a high aspect ratio contact (HARQ) structure and/or a high aspect ratio trench (HART) structure.

The inventive concept has been described with reference to the attached drawings, but it is to be understood by an artisan that the inventive concept may be practiced by one of ordinary skill in the art in other specific forms without changing the technical concept or features of the inventive concept. Further, the above-described embodiments are examples and do not limit the scope of the rights of the inventive concept.

1. A plasma processing apparatus comprising:
a chamber configured to receive a gas;
a first electrode disposed in the chamber, the first electrode configured to receive a substrate loaded thereon;
a second electrode disposed in the chamber that is opposed to the first electrode;
a RF power source configured to be switched between an on-state and an off-state, the RF power source further configured to supply a source RF power to the first electrode or the second electrode and to supply a bias RF power to the first electrode in the on-state to generate an RF electric field between the first electrode and the second electrode that excites the gas in the chamber into a plasma state;
a first DC voltage supply configured to alternately supply a first DC voltage of negative polarity and a second DC voltage of negative polarity to the second electrode based on a state of the RF power source, wherein an absolute value of the second DC voltage is greater than an absolute value of the first DC voltage; and
a second DC voltage supply is configured to be turned on between a first cycle and a second cycle when the first DC voltage is output to supply a third DC voltage of positive polarity to the first electrode.

2. The plasma processing apparatus of claim 1, wherein the first DC voltage supply is configured to supply the first DC voltage to the second electrode When the RF power source is in the on-state, and to supply the second DC voltage to the second electrode when the RF power source is in the off-state.

3. The plasma processing apparatus of claim 1, wherein the second DC voltage supply is configured to be turned on when the first cycle is completed and turned off when the second cycle is started.

4. The plasma processing apparatus of claim 1, wherein the second DC voltage supply is configured to be turned on when the first cycle is completed and turned off before the second cycle is started.

5. The plasma processing apparatus of claim 1, wherein the second DC voltage supply is configured to be turned on after a predetermined period of time has elapsed from when the first cycle is completed.

6. The plasma processing apparatus of claim 5, wherein the predetermined period of time comprises a time period that elapses when a number of electrons that generate a plasma potential in the chamber becomes less than a predetermined value.

7. The plasma processing apparatus of claim 5, wherein the second DC voltage supply is configured to be turned off when the second cycle is started.

8. The plasma processing apparatus of claim 5, wherein the second DC voltage supply is configured to be turned off prior to the second cycle being started.

9. (canceled)

10. A plasma processing apparatus comprising:
a chamber;
a first electrode disposed in the chamber, the first electrode configured to receive a substrate loaded onto the first electrode;
a second electrode disposed in the chamber to oppose to the first electrode;
a RF power source configured to be turned on from a first time to a second time to supply a source RF power to the first electrode or the second electrode and to supply a bias RF power to the first electrode, and to be turned off from the second time to a third time;
a first DC voltage supply configured to supply a first DC voltage of negative polarity to the second electrode from the first time to the second time and to supply a second DC voltage of negative polarity to the second electrode from the second time to the third time, wherein an absolute value of the second DC voltage is greater than an absolute value of the first DC voltage; and
a second DC voltage supply, wherein the second DC voltage supply is turned on between the second time and the third time to supply a third DC voltage of positive polarity to the first electrode.

11. The plasma processing apparatus of claim 10, wherein the second DC voltage supply is turned on at the second time and turned off at the third time.

12. The plasma processing apparatus of claim 10, wherein the second DC voltage supply is configured to be turned on at the second time and turned off before the third time.

13. The plasma processing apparatus of claim 10, wherein the second DC voltage supply is configured to be turned on between the second time and the third time.

14. The plasma processing apparatus of claim 13, wherein the second DC voltage supply is configured to be turned on when a number of electrons that generate a plasma potential in the chamber becomes less than a predetermined value after the second time has elapsed.

15. The plasma processing apparatus of claim 13, wherein the second DC voltage supply is configured to be turned off at the third time.

16. The plasma processing apparatus of claim 13, wherein the second DC voltage supply is configured to be turned off before the third time.

17. A method for manufacturing a semiconductor device performed by a plasma processing apparatus, the apparatus comprising a chamber, a first electrode disposed in the chamber, wherein a substrate is loaded on the first electrode, a second electrode disposed in the chamber to oppose to the first electrode, a RF power source configured to supply a source RF power to the first electrode or the second electrode and to supply a bias RF power to the first electrode when it is turned on to generate an RF electric field between the first electrode and the second electrode that excites a gas in the chamber into a plasma state, a first DC voltage supply configured to supply a first DC voltage or a second DC voltage of negative polarity to the second electrode, wherein an absolute value of the second DC voltage is greater than an absolute value of the first DC voltage, and a second DC voltage supply configured to supply a third DC voltage of positive polarity to the first electrode when it is turned on,
wherein the method comprises:
supplying the first DC voltage to the second electrode from the first DC supply and turning on the RF power source from a first time to a second time, to etch the substrate to form a contact hole or a trench therein having a first depth;
turning off the RF power source, supplying the second DC voltage to the second electrode from the first DC voltage supply from the second time to a third time, and turning on the second DC voltage supply between the second time and the third time to migrate anions and electrons in the chamber into the contact hole or the trench; and
supplying the first DC voltage to the second electrode from the first DC voltage supply and turning on the RF power source from the third time to a fourth time, to etch the substrate so that the contact hole or the trench becomes deeper the first depth.

18. The method for manufacturing a semiconductor device performed by the plasma processing apparatus of claim 17, wherein the second DC voltage supply is turned on after the second time elapses.

19. The method for manufacturing a semiconductor device performed by the plasma processing apparatus of claim 18, wherein the second DC voltage supply is turned on when a number of electrons that generate a plasma potential in the chamber becomes less than a predetermined value after the second time has elapsed.

20. The method for manufacturing a semiconductor device performed by the plasma processing apparatus of claim 18, wherein the second DC voltage supply is turned off at the third time.

21. The method for manufacturing a semiconductor device performed by the plasma processing apparatus of claim 18, wherein the second DC voltage supply is turned off before the third time.

22. (canceled)
